(19) United States
(12) Patent Application Publication
(10) Pub. No.: US 2025/0386487 A1
(43) Pub. Date: Dec. 18, 2025

(54) MEMORY DEVICE AND MANUFACTURING METHOD THEREOF

(71) Applicant: NANYA TECHNOLOGY CORPORATION, New Taipei city (TW)

(72) Inventor: Chao-Wen LAY, New Taipei City (TW)

(21) Appl. No.: 18/740,524

(22) Filed: Jun. 12, 2024

(51) Int. Cl. H10B 12/00

(52) U.S. Cl. CPC H10B 12/485; H10B 12/34; H10B 12/053

(57) ABSTRACT

A manufacturing method of a memory device includes forming a trench in a substrate, forming a gate dielectric layer lining the trench, forming a word line in the trench and over the gate dielectric layer, etching the gate dielectric layer such that a top end of the gate dielectric layer is lower than a top surface of the substrate, forming a landing pad over the top end of the gate dielectric layer, forming a dielectric layer covering the word line, the landing pad, and the substrate, and forming a contact in the dielectric layer and in contact with the substrate and the landing pad.

### BACKGROUND

### FIELD OF DISCLOSURE

The present disclosure relates to a memory device and a manufacturing method thereof.

### DESCRIPTION OF RELATED ART

Memory cells in the dynamic random access memory (DRAM) have been scaled down continuously to achieve a larger number of the memory cells in a unit area. However, some issues of manufacturing the memory cells may arise from the scaling down process of DRAM. For example, the overlay between two different components may become difficult.

### SUMMARY

Some embodiments of the present disclosure provide a manufacturing method of a memory device including forming a trench in a substrate, forming a gate dielectric layer lining the trench, forming a word line in the trench and over the gate dielectric layer, etching the gate dielectric layer such that a top end of the gate dielectric layer is lower than a top surface of the substrate, forming a landing pad over the top end of the gate dielectric layer, forming a dielectric layer covering the word line, the landing pad, and the substrate, and forming a contact in the dielectric layer and in contact with the substrate and the landing pad.

In some embodiments, forming the landing pad includes forming a cap layer over the word line, forming a conductive layer lining the substrate, the gate dielectric layer and the cap layer, and etching the conductive layer until the top surface of the substrate is exposed.

In some embodiments, forming the cap layer over the word line includes forming a cap material layer overfilling the trench, and etching the cap material layer until the top end of the gate dielectric layer is exposed.

In some embodiments, a bottom of the landing pad is substantially level with a top surface of the cap layer.

In some embodiments, during etching the conductive layer, a top surface of the cap layer is exposed.

In some embodiments, after etching the gate dielectric layer, the top end of the gate dielectric layer is higher than the top surface of the word line and lower than the top surface of the substrate.

In some embodiments, forming the contact includes forming an opening in the dielectric layer exposing the substrate and the landing pad, and forming the contact in the opening.

In some embodiments, a top surface of the landing pad is level with a top surface of the substrate.

In some embodiments, a bottom of the landing pad is higher than a top surface of the word line.

In some embodiments, the landing pad is made of amorphous silicon.

Some embodiments of the present disclosure provide a memory device, including a substrate, a word line in the substrate, a gate dielectric layer lining the word line, a landing pad in contact with a top end of the gate dielectric layer and a sidewall of the substrate, a dielectric layer over the substrate, the word line and the landing pad, and a contact in the dielectric layer and in contact with the substrate and the landing pad.

In some embodiments, the top end of the gate dielectric layer is higher than a top surface of the word line is lower.

In some embodiments, the memory device further includes a cap layer over the word line and covered by the dielectric layer, in which a top surface of the cap layer is lower than the top surface of the landing pad.

In some embodiments, the top surface of the cap layer is substantially level with the bottom of the landing pad.

In some embodiments, a top surface of the landing pad is level with a top surface of the substrate.

In some embodiments, the landing pad is in contact with a sidewall of the dielectric layer.

In some embodiments, a bottom of the landing pad is higher than a top surface of the word line.

In some embodiments, the contact vertically overlaps with the gate dielectric layer.

In some embodiments, the landing pad is made of amorphous silicon.

In some embodiments, the dielectric layer is in contact with the landing pad and the contact.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of the memory device in some embodiments of the present disclosure.

FIGS. 2-11 illustrate cross-section views of a manufacturing method of a memory device in some embodiments of the present disclosure.

### DETAILED DESCRIPTION

Some embodiments of the present disclosure are related to a manufacturing method of a memory device. In the present disclosure, the landing area between a contact and the substrate is enlarged by forming a landing pad adjacent to and in contact with the protrusion portion of the substrate. Therefore, even if the contact is laterally shifted from the substrate, the contact is still in contact with the landing pad. The electrical connection between the contact and the substrate is still good.

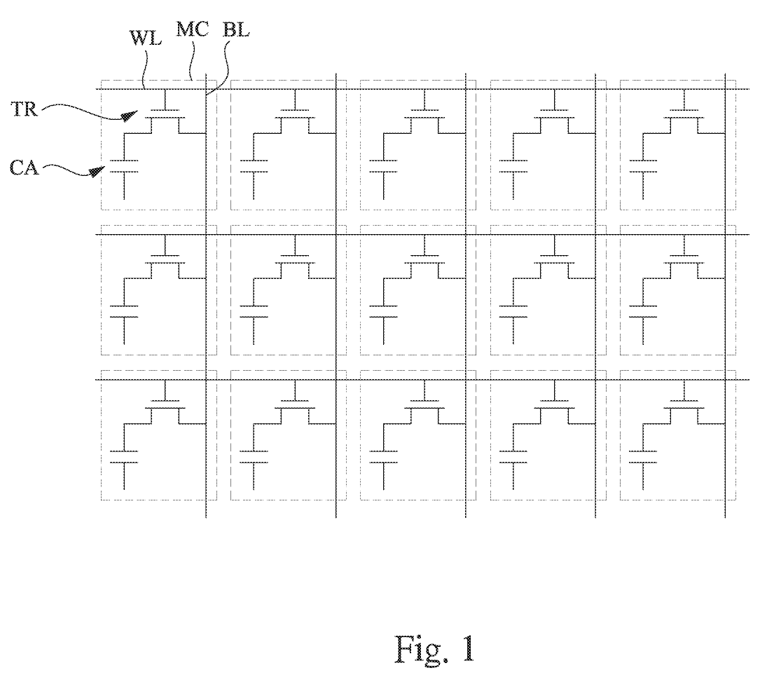

FIG. 1 illustrates a circuit diagram of the memory device in some embodiments of the present disclosure. Referring to FIG. 1, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. A bit line BL is electrically connected to a source/drain region of the transistor TR, and a word line WL is electrically connected to a gate region of the transistor TR. The capacitor CA is electrically connected to the other source/drain region of the respective transistor. In some embodiments, the contact used to connect the capacitor CA or the bit line BL may be laterally shifted from the source/drain region of transistor TR, and a landing pad is provided to enlarge the landing area between the contact and the source/drain region of transistor TR.

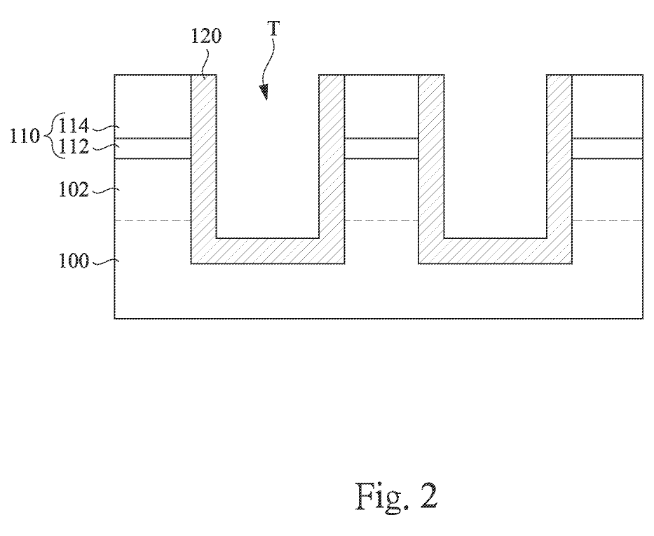

FIGS. 2-11 illustrate cross-section views of a manufacturing method of a memory device in some embodiments of the present disclosure. Referring to FIG. 2, a substrate 100 is provided. In some embodiments, the substrate 100 may be made of silicon. The substrate 100 may include a doped region 102 at the upper portion of the substrate 100. The doped region 102 and the substrate 100 have opposite conductivity types. For example, if the substrate 100 is a p-type substrate, the doped region 102 is an n-type doped region. If the substrate 100 is an n-type substrate, the doped region 102 is a p-type doped region.

Subsequently, trenches T are formed in the substrate 100. Specifically, a hard mask 110 is formed over the substrate 100, and then the substrate 100 is patterned by using the hard mask 110. In some embodiments, the hard mask 110 may include one or more dielectric layer, such as hard mask layers 112 and 114. In some embodiments, the hard mask layers 112 and 114 may be made of silicon oxide, silicon nitride or the like. For example, the hard mask layer 112 is made of silicon oxide, and the hard mask layer 114 is made of silicon nitride. Subsequently, gate dielectric layers 120 are formed lining the trenches T. In some embodiments, the gate dielectric layers 120 further cover the top surface of the hard mask 110. In some embodiments, the gate dielectric layers 120 may be made of silicon oxide, silicon nitride or the like.

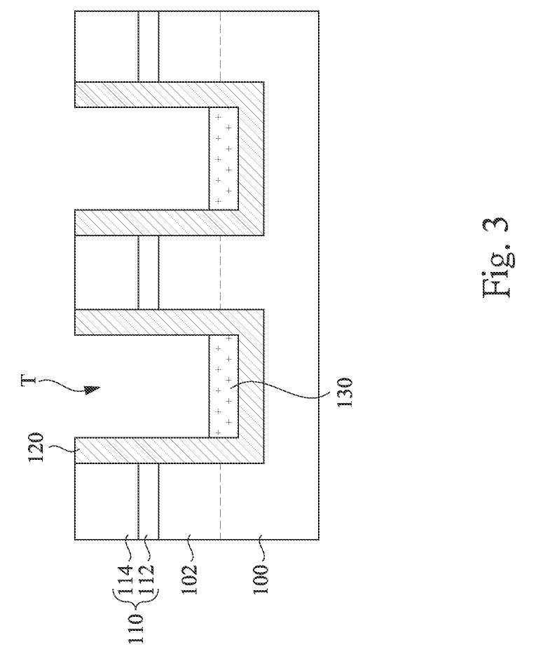

Referring to FIG. 3, word lines 130 are formed in the trenches T and over the gate dielectric layers 120. Specifically, the word lines 130 may be formed by filling a conductive layer overfilling the trenches T. A planarization process may be performed to remove the excess portion of the conductive layer until the top surface of the hard mask 110 is exposed, and then an etching back process is performed to lower the top surface of the conductive layer in the trench T. Accordingly, the word lines 130 are formed in the trenches T. The top surfaces of the word lines 130 may be lower than the top surface of the substrate 100 and the bottom of the hard mask 110. In some embodiments, the word lines 130 may be made of conductive material, such as metal.

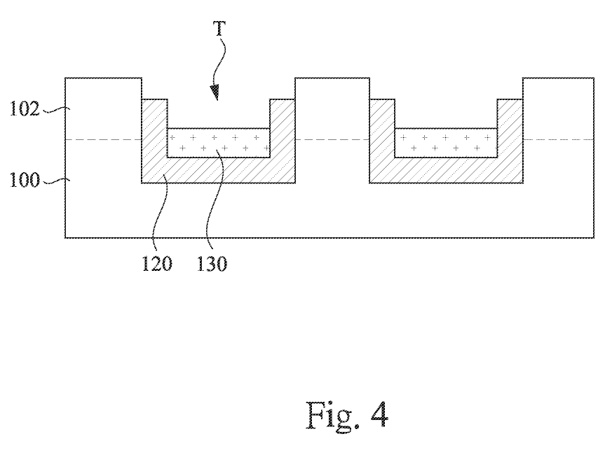

Referring to FIG. 4, the hard mask 110 is removed, and then the top surfaces of the gate dielectric layers 120 are lowered. Specifically, the hard mask 110 may be removed by an anisotropic etching process until the top surface of the substrate 100 is exposed. During the removal of the hard mask 110, portions of the gate dielectric layers 120 at the sidewall of the hard mask 110 are also removed. After the hard mask 110 is removed, the gate dielectric layers 120 are further etched, such that top ends of the gate dielectric layer 120 are lower than the top surface of the substrate 100 and higher than the top surfaces of the word lines 130. The word line 130 may serve as the gate electrode of the transistor TR in FIG. 1, the gate dielectric layer 120 may serve as the gate dielectric layer of the transistor TR in FIG. 1, the substrate 100 may serve as the channel region of the transistor TR in FIG. 1, and the doped regions 102 may serve as source/drain regions of the transistor TR in FIG. 1.

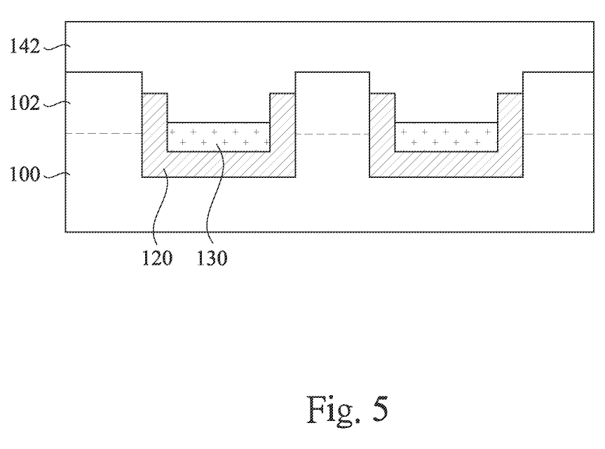

Referring to FIG. 5, a cap material layer 142 is formed overfilling the trench T. The cap material layer 142 covers the substrate 100, the gate dielectric layer 120, and the word line 130. In some embodiments, the cap material layer 142 may be made of silicon oxide, silicon nitride or the like. In some embodiments, the material of the cap material layer 142 may be different from the material of the gate dielectric layer 120.

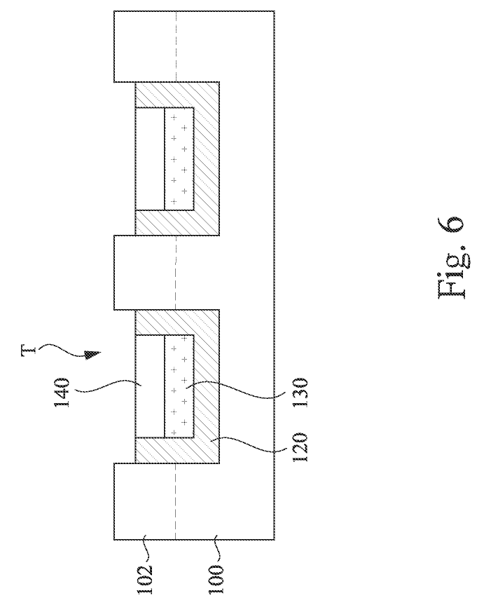

Referring to FIG. 6, a planarization process may be performed to remove the excess portion of the cap material layer 142 until the top surface of the substrate 100 is exposed, and then an etching back process is performed until the top ends of the gate dielectric layers 120 are exposed. Accordingly, the cap layers 140 are formed over the word lines 130, and the top surfaces of the gate dielectric layers120 are substantially level with the top surfaces of the cap layers 140.

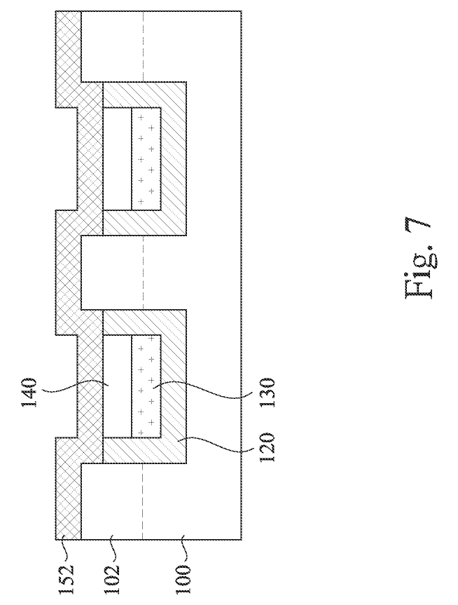

Referring to FIG. 7, a conductive layer 152 is formed lining the substrate 100, the gate dielectric layers 120, and the cap layers 140. In some embodiments, the conductive layer 152 may be amorphous silicon or metal.

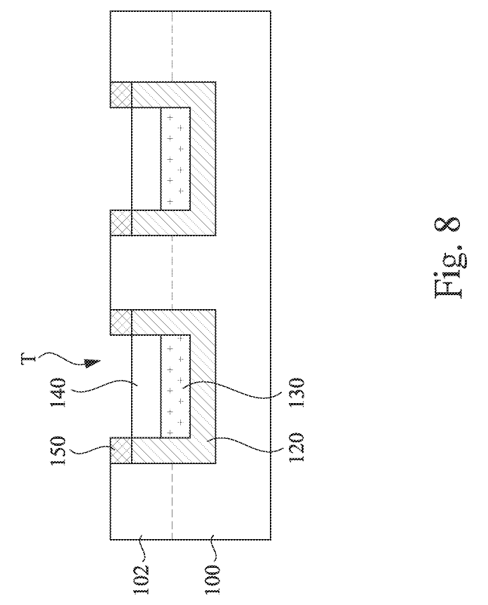

Referring to FIG. 8, landing pads 150 are formed over the top ends of the gate dielectric layers 120. Specifically, the landing pads 150 are formed by etching the conductive layer 152 until the top surface of the substrate 100 is exposed. During forming the landing pads 150 by etching the conductive layer, top surfaces of the cap layers 140 are also exposed. The etching may be an anisotropic etching process, such that a horizontal portion of the conductive layer 152 is removed, and a vertical portion of the conductive layer 152 remains at the sidewalls of the substrate 100. The vertical portion of the conductive layer 152 becomes the landing pads 150 over the gate dielectric layers 120, and the top surfaces of the landing pads 150 are substantially level with the top surfaces of the substrate 100. The landing pads 150 are in contact with the sidewalls of the substrate 100. Since the top surfaces of the cap layers 140 are substantially level with the top surfaces of the gate dielectric layers 120, the top surfaces of the landing pads 150 are higher than the top surfaces of the cap layers 140, and the bottoms of the landing pads 150 are substantially level with the top surfaces of the cap layers 140. The bottoms of the landing pads 150 are also higher than the top surfaces of the word lines 130.

The landing pad 150 is a conductive material formed in contact with the doped region 102 of the substrate 100, and is used to enlarge the landing area between the doped regions 102 of the substrate 100 and the component formed subsequently. The cap layer 140 may be used to electrically isolate the landing pad 150 and the word line 130. That is, after forming the landing pads 150, the landing pads 150 are not in contact with the word lines 130, and may be in contact with the cap layers 140.

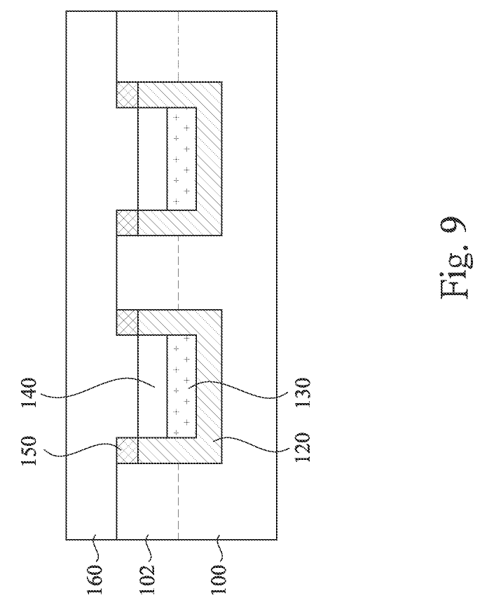

Referring to FIG. 9, a dielectric layer 160 is formed covering the word lines 130, the landing pads 150, the cap layers 140 and the substrate 100. In some embodiments, the landing pads 150 are in contact with the sidewall of the dielectric layer 160. In some embodiments, the dielectric layer 160 may be made of silicon oxide, silicon nitride, or the like.

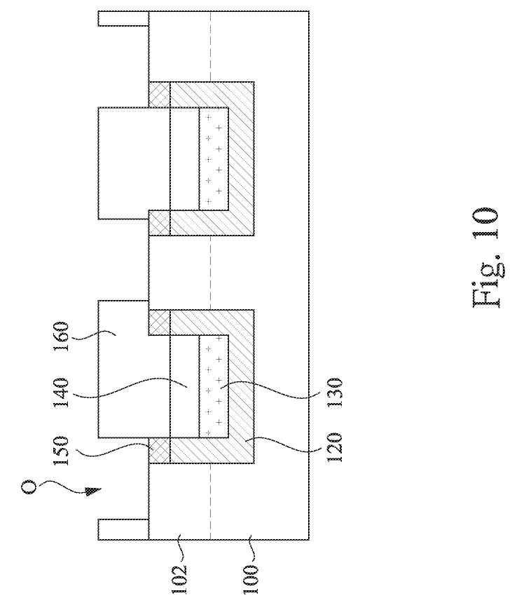

Referring to FIG. 10, openings O in the dielectric layer 160 exposing the substrate 100 and the landing pads 150 are formed. The openings O are used for forming the contacts in subsequent process. Ideally, the openings O expose the substrate 100. However, misalignment between the openings O and the substrate 100 may occur, such that the openings O may shift from the substrate 100 and further expose other regions. For example, the dielectric layer 160 may cover the cap layers 140, some of the landing pads 150, and a portion of the substrate 100. That is, some of the landing pads 150 are covered by the dielectric layer, and some of the landing pads 150 are exposed by the openings O. If the landing pads 150 are not provided, the openings O may further expose the gate dielectric layers 120, and the landing area between the doped region 102 of the substrate 100 and the component formed subsequently may be smaller.

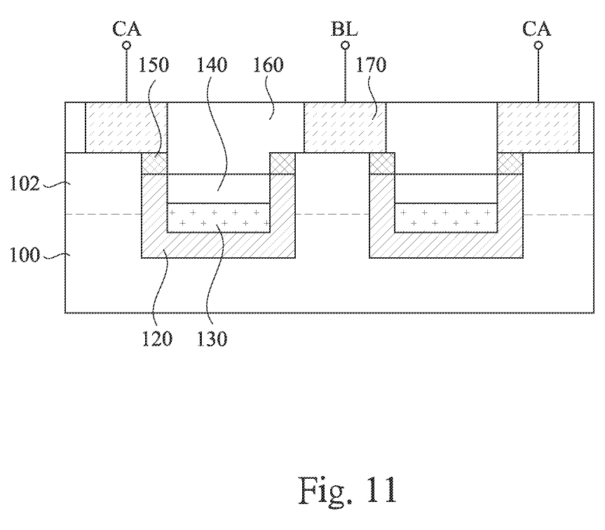

Referring to FIG. 11, contacts 170 are formed in the dielectric layer 160 and in contact with the substrate 100 and the landing pads 150. Specifically, a conductive material layer is formed overfilling the openings O in the dielectric layer 160. Specifically, a planarization process may be performed to remove the excess portion of the conductive material layer until the top surface of the dielectric layer 160 is exposed. The contacts 170 are formed over the substrate 100 and the landing pads 150 accordingly, and the contacts 170 vertically overlap with some of the gate dielectric layers 120. The contact 170 may be used to connect the respective doped regions 102 with the component formed subsequently, such as capacitor or bit line. For example, the contact 170 in contact with a doped region 102 adjacent to the word line 130 is connected to a capacitor CA, and the contact 170 in contact with the other doped region 102 adjacent to the word line 130 is connected to a bit line BL. After the contacts 170 are formed, the dielectric layer 160 is in contact with the contacts 170 and the landing pads 150.

The resulting device is shown in FIG. 11. The memory device includes a substrate 100, word lines 130, gate dielectric layers 120, cap layers 140, landing pads 150, a dielectric layer 160 and contacts 170. The word lines 130 are in the substrate 100. The gate dielectric layers 120 line the word lines 130, and are between the word lines 130 and the substrate 100. The landing pads 150 are in contact with top ends of the gate dielectric layers 120 and sidewalls of the substrate 100, and top surfaces of the landing pads 150 are substantially level with a top surface of the substrate 100. The dielectric layer 160 is over the substrate 100, the word lines 130 and the landing pads 150. The cap layers 140 are over the word lines 130 and covered by the dielectric layer 160, in which top surfaces of the cap layers 140 are lower than the top surfaces of the landing pads 150. The contacts 170 are in the dielectric layer 160 and in contact with the substrate 100 and the landing pads 150.

The landing pad 150 in the present disclosure is used to enlarge the landing area between the doped region 102 of the substrate 100 and the component formed subsequently, such as capacitor or bit line. The landing pads 150 are made of conductive material, such as polysilicon or metal, and the landing pads 150 are in contact with the doped regions 102 of the substrate 100. Therefore, if the contacts 170 are not perfectly aligned with the doped regions 102 of the substrate 100 (i.e. if the contacts 170 are shifted from the doped regions 102), the contacts 170 are still in contact with the landing pads 150 adjacent to the doped region 102. That is, the contact 170 is able to have good electrical connection with the doped regions 102 even if the contact 170 is misaligned with the doped region 102. Therefore, the component formed subsequently, such as capacitor or bit line, also has a good electrical connection with the doped region 102.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
forming a trench in a substrate;
forming a gate dielectric layer lining the trench;
forming a word line in the trench and over the gate dielectric layer;
etching the gate dielectric layer such that a top end of the gate dielectric layer is lower than a top surface of the substrate;
forming a landing pad over the top end of the gate dielectric layer;
forming a dielectric layer covering the word line, the landing pad, and the substrate; and
forming a contact in the dielectric layer and in contact with the substrate and the landing pad.

2. The manufacturing method of claim 1, wherein forming the landing pad comprises:
forming a cap layer over the word line;
forming a conductive layer lining the substrate, the gate dielectric layer and the cap layer; and
etching the conductive layer until the top surface of the substrate is exposed.

3. The manufacturing method of claim 2, wherein forming the cap layer over the word line comprises:
forming a cap material layer overfilling the trench; and
etching the cap material layer until the top end of the gate dielectric layer is exposed.

4. The manufacturing method of claim 2, wherein a bottom of the landing pad is substantially level with a top surface of the cap layer.

5. The manufacturing method of claim 2, wherein during forming the landing pad by etching the conductive layer, a top surface of the cap layer is exposed.

6. The manufacturing method of claim 1, wherein after etching the gate dielectric layer, the top end of the gate dielectric layer is higher than the top surface of the word line and lower than the top surface of the substrate.

7. The manufacturing method of claim 1, wherein forming the contact comprises:
forming an opening in the dielectric layer exposing the substrate and the landing pad; and
forming the contact in the opening.

8. The manufacturing method of claim 1, wherein a top surface of the landing pad is level with a top surface of the substrate.

9. The manufacturing method of claim 1, wherein a bottom of the landing pad is higher than a top surface of the word line.

10. The manufacturing method of claim 1, wherein the landing pad is made of amorphous silicon.

11. A memory device, comprising:
a substrate;
a word line in the substrate;
a gate dielectric layer lining the word line;
a landing pad in contact with a top end of the gate dielectric layer and a sidewall of the substrate;
a dielectric layer over the substrate, the word line and the landing pad; and
a contact in the dielectric layer and in contact with the substrate and the landing pad.

12. The memory device of claim 11, wherein the top end of the gate dielectric layer is higher than a top surface of the word line is lower.

13. The memory device of claim 11, further comprising:
a cap layer over the word line and covered by the dielectric layer, wherein a top surface of the cap layer is lower than the top surface of the landing pad.

14. The memory device of claim 13, wherein the top surface of the cap layer is substantially level with a bottom of the landing pad.

15. The memory device of claim 11, wherein a top surface of the landing pad is level with a top surface of the substrate.

16. The memory device of claim 11, wherein the landing pad is in contact with a sidewall of the dielectric layer.

17. The memory device of claim 11, wherein a bottom of the landing pad is higher than a top surface of the word line.

18. The memory device of claim 11, wherein the contact vertically overlaps with the gate dielectric layer.

19. The memory device of claim 11, wherein the landing pad is made of amorphous silicon.

20. The memory device of claim 11, wherein the dielectric layer is in contact with the landing pad and the contact.
